(19) United States
(12) Patent Application Publication
(10) Pub. No.: US 2023/0270016 A1
(43) Pub. Date: Aug. 24, 2023

(54) PIEZOELECTRIC TRANSDUCER WITH ENCAPSULATION, AND METHOD FOR ADJUSTING THE ELECTROMECHANICAL PROPERTIES OF THE PIEZOELECTRIC TRANSDUCER

(71) Applicant: TDK Electronics AG, München (DE)

(72) Inventors: Sandro Kappert, Finsterwalde (DE); Stefan Sax, Graz (AT); Dominik Taferner, Preding (AT)

(21) Appl. No.: 18/020,284

(22) PCT Filed: Jul. 23, 2021
(86) PCT No.: PCT/EP2021/070721

§ 371 Date: Feb. 8, 2023

(30) Foreign Application Priority Data
Aug. 13, 2020 (DE) 10 2020 121 337.9

(51) Int. Cl. H10N 30/88; H10N 30/02; H10N 30/30; H10N 30/857

(52) U.S. Cl. CPC H10N 30/883; H10N 30/02; H10N 30/302; H10N 30/857

(57) ABSTRACT

--A piezoelectric transducer including a piezoelectric element and an encapsulation which encloses the piezoelectric element. The encapsulation is configured to set the electro-mechanical properties of the transducer. For example, the hardness of a material of the encapsulation and/or or the geometry of the encapsulation is suitably selected.--

The present invention relates to a piezoelectric transducer that can be used, for example, as a sensor for an exerted force and/or deformation. In particular, the transducer may be designed to deform, in particular to bend, in response to an applied force and to output an electrical voltage. Alternatively, the transducer may be an actuator that undergoes a deformation when an electrical voltage is applied, thereby delivering a force to the outside.

Sensor systems for the detection of mechanical forces and/or deformation can be used in various application fields to control processes and ensure a safe process flow. A mechanical deformation can be caused, for example, by a simple contact, especially a touch, a collision of moving machines or machine parts or a torsion or twisting at the sensor system. Due to the increased use of autonomous systems and ever greater automation of process and production flows, deformation sensors are becoming more and more important.

Known are active, in particular piezo-active sensors as shown, for example, in EP 1 301 762 B1, as well as passive, in particular resistive or capacitive sensors as shown, for example, in EP 2 899 521 A1.

To improve such sensor systems, in particular to increase the signal strength, the piezoelectric component is, for example in US 4 634 917 A, formed as a multilayer structure. Furthermore, the layer thickness of a piezoelectric material can also be increased. However, such measures often lead to a significant increase in process complexity. In addition, it is known to amplify the electrical signal by electrical amplification components. However, this often leads to an increased influence of disturbance variables, for example electromagnetic interference (EMI) from the environment and to a poorer signal-to-noise ratio.

It is an object of the present invention to provide an improved piezoelectric transducer and a method for adjusting the characteristics of a piezoelectric transducer.

According to a first aspect of the present invention, a piezoelectric transducer comprises a piezoelectric element and an encapsulation surrounding the piezoelectric element. In particular, the encapsulation is configured to adjust the electromechanical properties of the transducer.

The piezoelectric element comprises, for example, a polymer material as the piezoelectric material. The piezoelectric material is applied to a carrier, for example, by a printing or coating process. The carrier is formed, for example, as a plastic carrier. The carrier may also be formed as a composite, for example comprising plastic and a conductive material. In particular, the carrier may be formed as a printed circuit board.

The piezoelectric element can also be arranged as a standalone element. Thus, the piezoelectric element is not arranged on a support. For example, a piezoelectric material is formed as a foil, for example by foil drawing.

The encapsulation can completely enclose the piezoelectric element and, if applicable, a carrier. For example, the encapsulation is produced by a potting process. The encapsulation can form an outer surface of the transducer on which a force can be applied directly from the outside.

Such a transducer must have sufficient deformability under an expected force so that a sufficient electrical signal is generated. After the force is applied, it must return to its original position. In general, the greater the deformation and the more volume of piezoelectric material deformed at a given deformation speed, the greater the signal output. By suitable choice of encapsulation, the deformed volume of the piezoelectric material can be increased for the same applied force and/or the same deformation.

In particular, the encapsulation can be suitably selected in terms of its deformability. If a harder material is selected for the encapsulation, for example, a lower maximum deformation of the piezoelectric element occurs for the same force application. However, the deformation of the piezoelectric element extends over a larger volume of the piezoelectric material. In this way, for a given force or deformation, an encapsulation can be determined with a deformability at which the electrical signal generated by the piezoelectric element is maximum. In this case, both an increase in the hardness and a decrease in the hardness of the encapsulation material can cause a decrease in the signal output for a given force or deformation with otherwise equal construction of the piezoelectric element. Thus, the hardness of the encapsulation is optimally selected with respect to signal strength.

For example, a material with a Shore hardness D 30 to 40 is used for the encapsulation. Softer materials, for example with a Shore hardness from A 30, for example in the range between A 45 to A 55, can also be used.

Additionally or alternatively, the electro-mechanical properties of the transducer can be adjusted by the geometry of the encapsulation.

For example, the encapsulation has a curved surface on which the force acts from the outside. The piezoelectric element has a flat surface, for example. Due to the curved surface of the encapsulation, a deformation of a larger volume of the piezoelectric material and thus a signal amplification can be achieved under constant boundary conditions.

In various embodiments, the encapsulation may include a deformation area in which the piezoelectric element is arranged. In addition, the encapsulation may include a support area that supports the deformation area. One or more electronic components may be arranged in the support area. Due to the different geometric design, the support area can be clearly distinguished from the deformation area from the outside.

For example, the encapsulation can comprise a bridge-shaped geometry. In this way, an elastic holder of the piezoelectric element can be achieved. For example, the encapsulation comprises a deformation area in which the piezoelectric element is arranged and a support area which supports the sensor area. The deformation area may be integrally formed with the support area. The encapsulation may also have a different geometry that provides an elastic holder for the piezoelectric element.

In this way, the deformation of the piezoelectric element can be optimized. In addition, the piezoelectric element does not have to be clamped in an additional holder.

In a further embodiment, the encapsulation may also comprise a finger-shaped deformation area supported by a support area. The finger-shaped deformation area may extend upwardly from the support area. In this case, the transducer may be configured for application of a force to a side face of the finger-shaped deformation area. Again, the encapsulation sets the electromechanical properties of the piezoelectric element and may also provide elastic return to an original orientation. One or more electronic components may be arranged in the support area.

Overall, the electromechanical properties of the transducer can be set by a specific choice of the material properties of the encapsulation, such as the hardness of the material, and/or the geometry of the encapsulation. In this way, the encapsulation can be used to adjust how strongly and to what extent the piezoelectric element deforms under application of a force, so that the electrical signal generated by the piezoelectric element is adjusted and, in particular, the signal strength is increased. Thus, it is not necessary to modify the piezoelectric element to obtain an increase in signal strength. In addition, downstream electronics can be reduced in complexity and cost, and undesirable effects of amplifying electronics, such as degradation of the signal-to-noise ratio, can be reduced.

In addition, by a suitable choice of the encapsulation it is also possible to reduce the volume of a piezoelectric material of the piezoelectric element with the same signal strength.

In various embodiments, the transducer may include structures to improve the mechanical coupling of the piezoelectric element to the encapsulation.

For example, the piezoelectric element is arranged on a carrier, wherein the piezoelectric element and the carrier are enclosed by the encapsulation. The carrier may have structures by which the coupling to the encapsulation is improved. The structures may be in the form of protrusions, for example. The structures may be formed by initial shaping of the carrier, by removal of material from the carrier, or by addition of material to the carrier. For example, the structures are formed on side faces of the carrier, for example as a type of corrugation, or columnar structures are formed on a main face of the carrier, for example in the form of dowel pins. It is also possible to form the structures in the form of holes in the carrier, which are filled by the encapsulation.

In a further embodiment, the transducer has a further encapsulation, wherein the further encapsulation has a greater degree of hardness than the encapsulation. For example, the degree of hardness of the further encapsulation in Shore hardness D is at least twice as great as the degree of hardness of the encapsulation.

For example, the further encapsulation has a degree of hardness with a Shore hardness D greater than 80. For example, the encapsulation has a degree of hardness with a Shore hardness between A 30 and D 40, in particular between A 35 and D 40.

The further encapsulation encloses one or more electronic components, for example, and may be configured to protect the components from excessive mechanical deformation. The electronic components are connected to the piezoelectric element and serve, in particular, to process the signal generated by the piezoelectric element. The encapsulation described above may completely enclose the further encapsulation.

The further encapsulation may, for example, also enclose an interface of the electronic components to an electrical connection, for example a connecting wire or a conductor path. For example, the further encapsulation also encloses a carrier in areas, in particular if the electronic component is arranged on the carrier. However, the further encapsulation should not enclose a too large area of the carrier so that it does not hinder deformation of the piezoelectric element too much.

The further encapsulation can be applied in a potting process like the encapsulation described above. For example, the one or more electronic components are first electrically connected to the piezoelectric element and then the further encapsulation is applied around the electronic components. Subsequently, the encapsulation described above is formed around, in particular around the further encapsulation and the piezoelectric element.

According to a further aspect of the present invention, a method for setting electromechanical properties of a transducer is disclosed. In particular, the transducer may be the transducer described above and may have any of the properties described above.

A piezoelectric element is provided. The piezoelectric element can be arranged on a carrier or can be configured as carrier-free. One or more electronic components can also be provided and electrically connected to the piezoelectric element.

Thereafter, the piezoelectric element and, if applicable, the carrier and, if applicable, the electronic components are enclosed by an encapsulation. In particular, the encapsulation can be formed in a potting process.

Optionally, a further encapsulation can be formed around the one or more electronic components prior to potting the encapsulation. This encapsulation can also be formed in a potting process. When forming the further encapsulation, the one or more electronic components may already be connected to the piezoelectric element.

A force is then applied to the transducer. For example, a predetermined force or predetermined deformation is applied over a predetermined time course. An electrical signal generated by the transducer due to the piezoelectric effect is measured. It is then determined whether the measured electrical signal has a desired value. For example, the desired value may be a sufficiently high signal strength. The desired value can also be a maximum in the signal strength if several measured values of identically constructed transducers with encapsulation of different degrees of hardness are available.

Depending on whether the measured value corresponds to a desired value or not, further transducers are manufactured as per the steps described above, the transducers differing only in the encapsulation, in particular in the degree of hardness of the encapsulation.

For example, a specific class of material is selected for encapsulation, such as a crosslinked polymer like polyurethane. The polymer has a main group and is crosslinked by forming side chains through reaction with further monomers. By increasing the degree of crosslinking, the mechanical strength of the material can be increased. By modifying the initial polymer, more side chains can be formed and the degree of crosslinking can be increased.

For example, the steps are repeated until a degree of hardness is found at which the measured signal has a desired value.

In accordance with a further aspect of the present invention a piezoelectric transducer is disclosed, comprising a piezoelectric element and an encapsulation enclosing the piezoelectric element. The encapsulation comprises a deformation area in which the piezoelectric element is arranged, and a support area which supports the deformation area. The transducer may have any of the features of the transducers described above. The encapsulation may, but need not, be configured to adjust the electromechanical properties of the transducer.

For example, the deformation area and the support area of the encapsulation have geometries that are clearly distinguishable from the outside. One or more electronic components can be arranged in the support area.

For example, the encapsulation may have a bridge-like geometry as described above and/or may have a finger-like deformation area.

The present invention encompasses several aspects, in particular devices and methods. The embodiments described for one of the aspects apply accordingly to the other aspect.

In addition, the description of the subjects matter specified here is not limited to the individual specific embodiments. Rather, the features of the individual embodiments can be combined with each other - as far as technically reasonable.

In the following, the subjects matter specified here are described in more detail on the basis of schematic embodiments.

It shows:

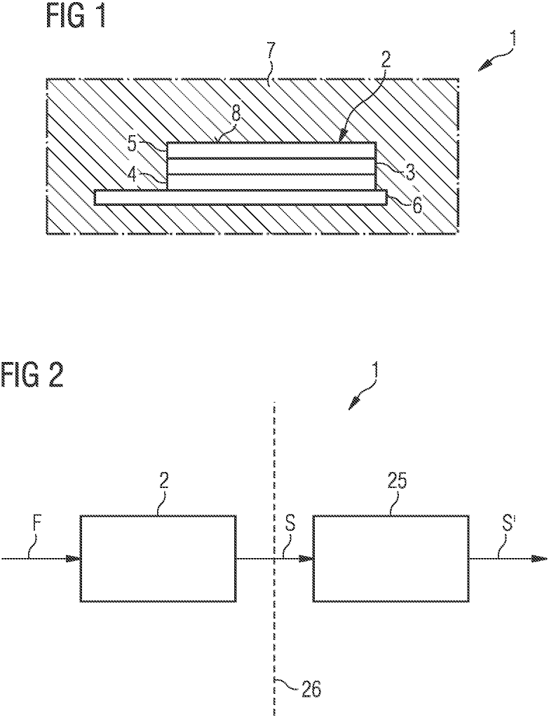

FIG. 1 an embodiment of a piezoelectric transducer in a schematic sectional view,

FIG. 2a a schematic diagram of signal generation in a piezoelectric transducer,

FIGS. 3a, 3b the piezoelectric transducer of FIG. 1 under application of a force in a schematic sectional view and in an oblique plan view,

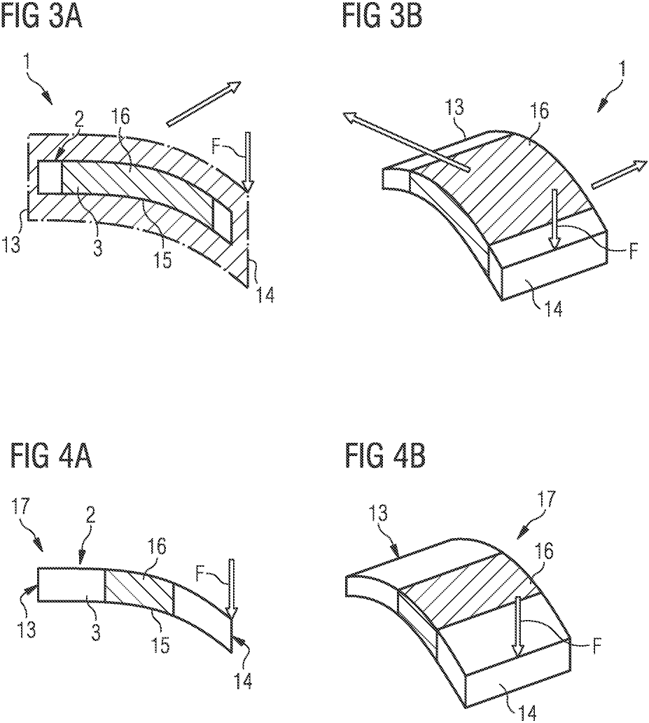

FIGS. 4a, 4b for comparison another piezoelectric transducer under application of a force in a schematic sectional view and in an oblique plan view,

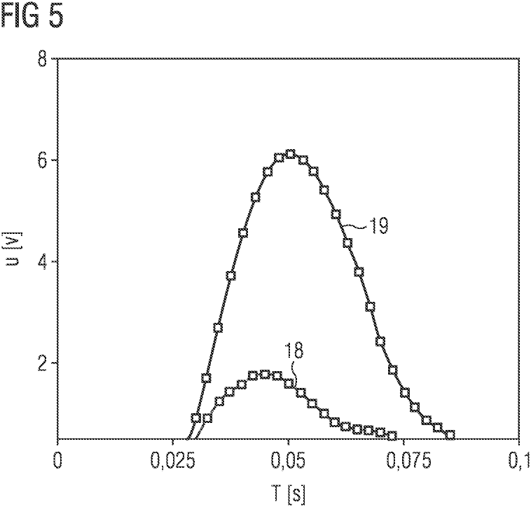

FIG. 5 a measurement curve of an output voltage under application of a force over a specified period for transducers with encapsulations of different degrees of hardness,

FIG. 6A an embodiment of a carrier for a transducer in a top view,

FIG. 6B an embodiment of a transducer with the carrier shown in FIG. 6A in a perspective, partially sliced view,

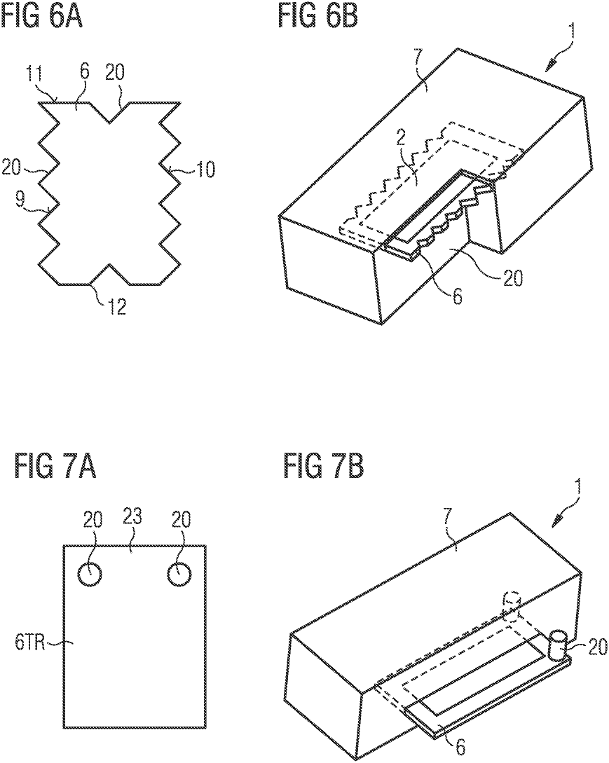

FIG. 7A an embodiment of a carrier for a transducer in a top view,

FIG. 7B an embodiment of a transducer with the carrier shown in FIG. 7A in a perspective, partially sliced view,

FIG. 8 a measurement curve of an output voltage under application of a force over a specified period for transducers with a carrier with or without structures for mechanical coupling to the encapsulation,

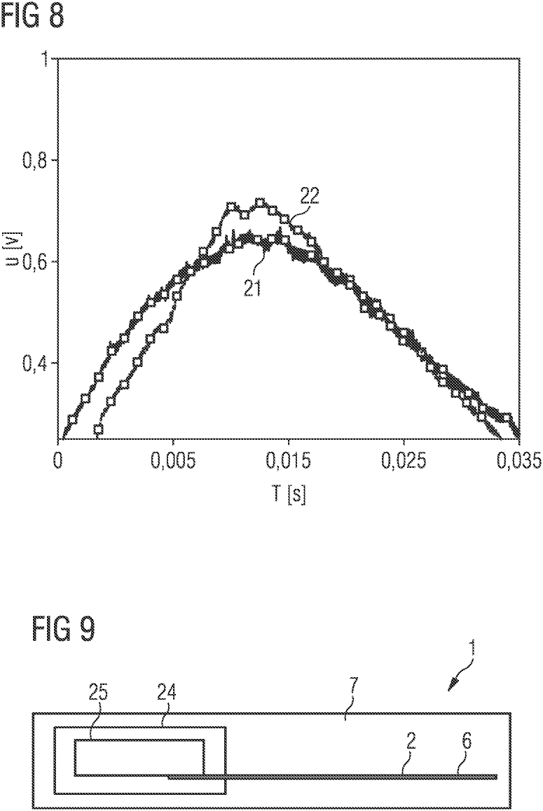

FIG. 9 an embodiment of a piezoelectric transducer in a schematic sectional view,

FIG. 10 embodiments of a piezoelectric transducer in a three-dimensional view,

FIG. 11 an embodiment of a transducer in a side view,

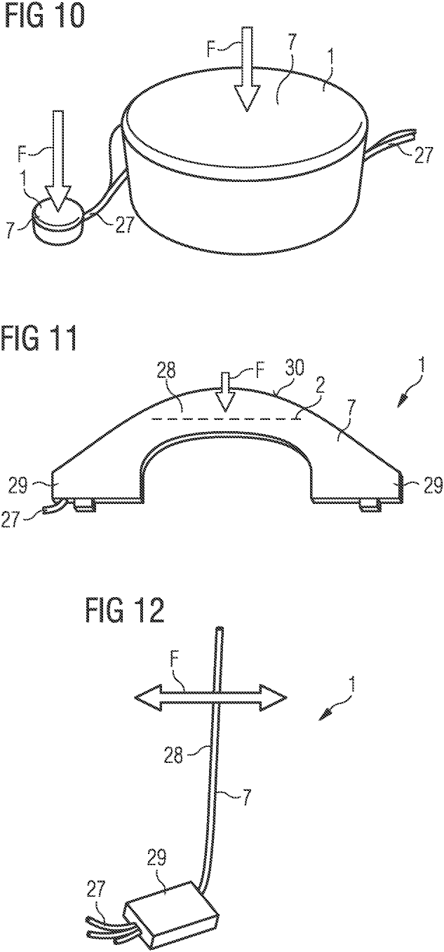

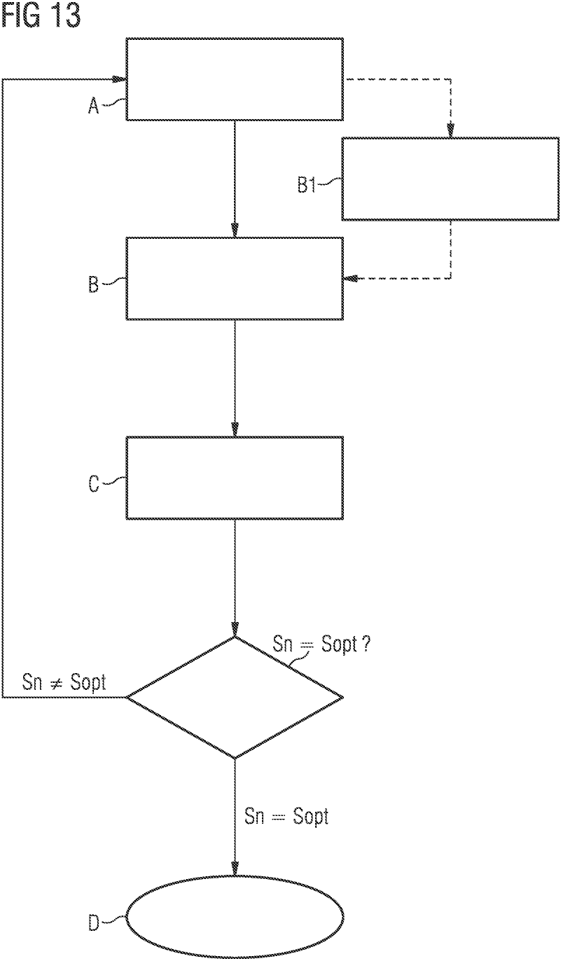

FIG. 12 an embodiment of a transducer in a three-dimensional view,

FIG. 13 a method for setting the electromechanical properties of a transducer in a schematic flow chart.

Preferably, in the following figures the same reference signs refer to functionally or structurally corresponding parts of the various embodiments.

FIG. 1 shows an embodiment of a piezoelectric transducer 1 in schematic sectional view. In particular, it is a sensor for detecting the application of a mechanical force. For example, it is a transducer that is designed to deform, in particular to bend, when a force is applied and to output an electrical signal as a function of the deformation.

The transducer 1 comprises a piezoelectric element 2. The piezoelectric element 2 comprises a piezoelectric material 3 arranged between two electrodes 4, 5. The piezoelectric material 3 and the electrodes 4, 5 are formed in layers.

For example, the piezoelectric material 3 comprises a polymer or consists, at least for the most part, of a polymer. In embodiments, the piezoelectric material 3 may also be formed as a ceramic. Overall, polymer materials are more flexible than ceramic materials and therefore more deformable. Also, too much bending deformation must often be avoided with ceramic materials due to their brittleness. However, the signal strength of polymer materials is usually lower than that of ceramic materials.

A suitable polymer material is, for example, a ferroelectric polymer such as PVDF and its copolymers. For example, PVDF:TrFE is suitable. Suitable electrode materials are, for example, PEDOT:PSS, carbon, Ag, Cr or Ni.

The piezoelectric element 2 is arranged in this case on a carrier 6. The piezoelectric material 3 is applied to the carrier 6 in a coating or printing process, for example. In particular, it may be a spin coating process or a screen printing process. It is also possible to produce the piezoelectric material 3 as a drawn foil. In this case, a carrier 6 is not absolutely necessary. The piezoelectric element 2 can also have a multilayer structure, i.e. several layers of piezoelectric material 3 and electrodes 4, 5.

The electrodes 4, 5 can be applied to the piezoelectric material 3, for example, by a coating process, such as a CVD or PVD process.

The carrier 6 is here in the form of a plate. The carrier 6 comprises an insulating material. For example, the carrier 6 comprises polyimide as material or consists of polyimide. The carrier 6 can be designed as a printed circuit board that has conductor tracks. One or more electronic components 25 can also be arranged on the carrier 6 (see e.g. FIG. 9).

The piezoelectric element 2 and the carrier 6 as well as optionally available electronic components are enclosed by an encapsulation 7. The encapsulation 7 comprises as material, for example, polyurethane, epoxy resin, silicone, rubber, polybutadiene or a thermoplastic elastomer. The encapsulation 7 is designed, for example, as a potting material. For this purpose, the piezoelectric element 2 with carrier 6 and optionally existing electronic components is positioned in a mold and then the encapsulation material is applied around the composite by a potting process, for example by injection molding, overmolding or a defined delivery of a liquid (“dispensing”).

The encapsulation 7 may completely enclose the piezoelectric element 2, the carrier 6, and the optionally present electronic components 25. The encapsulation 7 may be configured to allow an external force to act directly on the encapsulation 7. In particular, the encapsulation 7 completely encloses the composite of piezoelectric element 2 and carrier 6 on the upper side 8, i.e. on the side facing away from the carrier 6. In addition, the longitudinal and broad sides are also enclosed by the encapsulation 7.

The encapsulation 7 is configured to set the electro-mechanical properties of the transducer 1. In particular, the degree of hardness of the encapsulation 7 can be selected in such a way that an optimum signal strength of the piezoelectric element 2 is achieved. On the one hand, the encapsulation 7 should be sufficiently flexible to allow deformation, in particular bending, of the transducer 1.

On the other hand, the choice of the degree of hardness of the encapsulation 7 can set the volume of a deformed region of the piezoelectric element 2 and, in particular, of the piezoelectric material 3 when a force is applied. In particular, when the degree of hardness is increased, a larger volume of the piezoelectric element 2 can be “activated”, in particular deformed, and thus contribute to the electrical signal generated. The encapsulation 7 can be selected in such a way that the signal strength is optimized, hence, for example, no further improvement in the signal strength can be obtained when the degree of hardness of the optimal encapsulation is changed. The influence of the encapsulation 7 on the “activated” volume is explained in detail in FIGS. 3a to 4b.

In addition to this, the encapsulation 7 can also provide protection against external mechanical or chemical influences.

FIG. 2 shows a principle diagram of the signals S, S′ generated and processed in a transducer 1, for example the transducer 1 of FIG. 1, when the transducer 1 is used as a sensor.

The transducer 1 comprises the piezoelectric element 2 which deforms when an external force F is applied. In particular, the transducer 1 may be designed for bending the piezoelectric element 2.

The mechanical input signal, in particular a force F, is converted by the piezoelectric element 2 into an electrical signal S due to the piezoelectric effect, so that an electromechanical conversion takes place. This can be, for example, a generated voltage or a generated current flow.

The signal S output by the piezoelectric transducer 2 can then be transmitted via an electrical interface, e.g. a conductor track or a wire, to electronic components 25 (see e.g. FIG. 9) and suitably processed. For example, an analog-digital signal conversion and/or an amplification and/or filtering of the signal S takes place here.

The signal S′ processed in this way is then output externally to a higher-level control and/or regulation system. It is also possible for the transducer 1 to comprise no further electronic components 25, so that the signal S is output directly to the outside.

The task now is to set the transducer 1 by suitable selection of the encapsulation 7 in such a way that the expected physical input signal, i.e. an expected value of a force F or an expected value of a deformation, can be reliably detected and generates as large a signal S′ as possible at the output of the piezoelectric element 2. In this case, an expected time course of the force and/or deformation is also specified.

With a suitable choice of encapsulation 7, the required signal quality can thereby be obtained without having to change the structure of the piezoelectric element 2. In addition, the electronic amplification of the signal S generated by the piezoelectric element 2 can be reduced and thus the problems of noise and consequently reduced signal quality that occur with electronic amplification can be reduced. Thus, by suitable choice of the encapsulation 7, the signal S′ output from transducer 1 can be significantly increased, wherein the demands on the electronics can be reduced while maintaining the same sensitivity.

FIGS. 3a, 3b schematically show the behavior of a transducer 1 with encapsulation 7, in particular the transducer 1 from FIG. 1. The transducer 1 can be configured with or without a carrier 6.

FIG. 3a schematically shows the piezoelectric element 2 encapsulated in an encapsulation 7. The transducer 1 can also comprise further elements. In FIG. 3b, only the piezoelectric element 2 is shown for reasons of illustration; the existing encapsulation 7 is not shown here.

For comparison, FIGS. 4a, 4b show the behavior of a transducer 17 without encapsulation 7. There may also be an encapsulation 7 with a much lower degree of hardness, i.e. a higher deformability, than in FIG. 3a.

By way of example, FIGS. 3a, 3b, 4a, 4b show the operation of the transducers 1, 17 when one end 13 is clamped on one side. When a force F is applied, the transducer thus bends downwards with its free end 14. The transducer 1, 17 can also be clamped on both sides, for example.

In both transducers 1, 17, a deformation occurs when an external force F is applied to the transducer 1, 17, in particular a deformation of the piezoelectric material 3. Due to the deformation and the resulting mechanical stress within the piezoelectric material 3, an electrical voltage is generated between the electrodes 4, 5.

In the present case, the piezoelectric material 3 deforms most strongly in a central area 15. Thus, the active area 16 of the transducer 1, in which the main part of the electrical signal is generated, is located in the central area 15. Outside the central area 15, the transducer 1 is passive due to the low deformation and contributes little to the output signal.

As can be seen in a comparison of FIGS. 3a with 4a and 3b with 4b, the active, i.e. deformed, area 16 of the transducer 1 of FIG. 3a is significantly larger than the active area 16 of the transducer 17. Thus, the encapsulation 17 causes the mechanical stresses to be transferred to a larger area when a force F is applied, and thus a larger volume of the piezoelectric material 3 is deformed. This can lead to an increase in the output signal.

The material of the encapsulation 7 and in particular its degree of hardness is now to be set in such a way that an expected force can be reliably detected and, in addition, as large a volume as possible acts as the active area 16. In this way, the output signal can be optimized.

In particular, the signal can be increased for a given deformation path, e.g. the path of the free end 14 when a force F is applied. However, for a given value of the force F, it must be taken into account that with an increase in the degree of hardness, less deformation takes place, i.e. the free end is not pressed down as much, which can again lead to a reduction in the signal.

FIG. 5 shows measurement curves of generated voltages U when a force F is applied over a time T for transducers 1 with different encapsulations 7. The transducers 1 are designed, for example, as shown in FIG. 1.

For measurement curve 18, a softer encapsulation material with a Shore A hardness of 45 to 55 was used. For measurement curve 19, a harder encapsulation material with a Shore hardness D of 30 to 40 was used. The measuring tools and test conditions for measuring the Shore hardnesses A and D, respectively, are somewhat different. Overall, the Shore A method is used for softer materials and the Shore D method is used for harder materials. A non-linear relationship can be established between the Shore A and Shore D measured values. According to this, 50 Shore A corresponds approximately to 10 Shore D.

As suitable materials those described for FIG. 1 are possible, whereby the degree of hardness can be suitably set by the exact composition.

Apart from the encapsulation 7, the transducers 1 measured were of identical construction. In particular, the transducers 1 were formed as follows, where length indicates the extension from one end 13 to the other end 14, as shown in FIG. 1. The width indicates the extension of the transducer 1 in a direction perpendicular to the length direction and perpendicular to the force direction F. The thickness or height indicates an expansion in the stacking direction of the piezoelectric material 3 on the support 6, equivalent to the force direction in FIG. 1.

Design of the composite of carrier and piezoelectric element:
length: 20 mm
width: 10 mm
piezoelectric material: polymer material, PVDF:TrFE; 10 µm thick; applied onto carrier by screen-printing
electrode material: PEDOT:PSS
carrier Material: Polyimide; 75 µm thick

Design of the encapsulation (external dimensions):
length 44 mm
width 13 mm
height 5 mm
material at 18: Shore hardness D 30 to 40
material at 19: Shore hardness A 45 to 55

Both transducers 1 were deformed in a test rig at the same deformation speed over the same deformation path. The deformation speed was 0.4 m/s and the deformation path was 4 mm. The transducers 1 were clamped on one side, with an area of 15 mm x 10 mm.

As can be seen, the stress generated is significantly greater with the harder encapsulation material 19 than with the softer encapsulation material 18. In particular, the stress is greater at its maximum by approximately a factor of 3.

This can be explained by the fact that a larger volume of piezoelectric material 3 is deformed with the harder encapsulation material 19, thus the active area 16 is larger than with the softer encapsulation material 18. This is similar to a comparison of the active areas 16 in FIGS. 3a, 3b and FIGS. 4a, 4b.

In principle, when optimizing the settings, it must be taken into account that with a harder material, a smaller maximum deformation of the transducer 1 occurs for a given force instead of a given deformation path, but the deformation affects a larger volume of the transducer 1.

In order to achieve the desired effect of signal amplification by the encapsulation 7, it may be advantageous to select an encapsulation 7 whose flexibility lies in a similar range to the flexibility of the piezoelectric element 2 or the composite of piezoelectric element 2 and carrier 6.

For example, a similar range is in a range with a deviation of +/- 50%. Such an encapsulation can also be chosen as a starting point in an optimization, and it may become apparent during the course of the optimization that a larger deviation is advantageous. For example, the modulus of elasticity can be used here to determine flexibility. The modulus of elasticity indicates the applied mechanical stress at which a material deforms.

For example, a transducer 1 comprising a piezoelectric element 2 with a ceramic, such as PZT on an aluminum support, has a much higher mechanical strength than a sensor comprising a piezoelectric element with a plastic, e.g. PVDF:TrFE on a polyimide support. The elastic moduli for a piezoelectric polymer such as PVDF:TrFE are at 3 to 10 GPa and for a support made of plastic such as polyimide range at 3 GPa. In comparison, the elastic moduli for a piezoelectric ceramic such as PZT are at 55 to 70 GPa and for an aluminum support at 70 GPa.

Due to the shown amplification of the generated signal with a suitable choice of the encapsulation 7, for example, a smaller layer thickness of the piezoelectric material 3 or a single-layer instead of a multilayer structure of the piezoelectric element 2 may be sufficient. Thus, manufacturing processes can be simplified and costs can be saved.

Furthermore, in addition to signal amplification, the encapsulation 7 can also ensure elastic deformation of the piezoelectric element 2 so that the piezoelectric element 2 returns to its original shape after force is applied. This is particularly advantageous for piezoelectric elements 2 in which the piezoelectric material 3 is formed as an standalone foil, i.e., without an additional carrier.

In addition or alternatively to the choice of the material of the encapsulation 7, a modified mechanical coupling of the piezoelectric element 2 to the encapsulation 7 can also be used to optimize the output signal S. In particular, this is possible by changing the shape of the carrier 6, as shown for example in the following embodiments.

FIG. 6A shows a top view of a carrier 6 for a piezoelectric material 3 in a transducer 1 such as shown in FIG. 1, in which structures 20 are provided to improve the coupling to an encapsulation 7. Thus, the carrier 6 and thus the piezoelectric material 3 can better follow the deformation of the encapsulation 7, i.e., the mechanical stresses of the encapsulation 7 are better transferred to the carrier 6.

The structures 20 are in the case configured as notches on lateral faces, in particular on longitudinal sides 9, 10. The structures 20 are also partially present on the broad sides 11, 12. In particular, the structures 20 are introduced directly into the material of the carrier 6.

FIG. 6B shows a transducer 1 with encapsulation 7, in which the carrier 6 has structures 20 to improve the coupling to the encapsulation 7. In the present case, the structures are formed on the longitudinal sides 9, 10. However, additional or alternative structures 20 may also be formed on the broad sides 11, 12. The structures 20 are introduced into the carrier 6, for example, mechanically by material removal.

FIG. 7A shows a further embodiment of a carrier 6 with structures 20 for improving the mechanical coupling to the encapsulation 7. In contrast to FIG. 6A, the structures 20 are formed here on the upper side 23 of the carrier 6.

In addition, the structures 20 are formed by adding material to the carrier 6. In the present case, the structures 20 are pin-shaped. The structures 20 can comprise the same material as the carrier 6. The structures may be in the form of fit-in elements and may be fitted into holes in the carrier 6. The structures 20 may also be formed integrally with the carrier 6 or be attached to the carrier 6 by adhesive bonding. It is also possible to have no fit-in elements in the holes, so that the holes are filled by the encapsulation 7. In this case, too, a more intimate connection between the carrier 6 and the encapsulation 7 can be achieved.

The structures 20 are filled with an insulating material throughout their internal volume, thus do not enclose other components such as electrical components. Thus, the structures 20 are only added to improve the coupling to the encapsulation 7 and do not have a dual function such as encapsulating an electrical component.

Overall, the structures 20 provide a more intimate connection of the carrier 6 to the encapsulation 7 so that the carrier 6, and thus the piezoelectric element 2, is deformed as well as possible when the encapsulation 7 is deformed.

FIG. 7B shows a transducer 1 with encapsulation 7, in which the carrier 6 has structures 20 as shown in FIG. 7A to improve the coupling to the encapsulation 7.

FIG. 8 shows measurement curves of stresses U generated when a force F is applied over a time T for transducers 1 with and without structures 20 for improved coupling to the encapsulation 7. The transducers 1 are designed as in the measurement curves in FIG. 5, wherein in this case an encapsulation material with a Shore hardness A 45 to 55 was used. The measurement curve 21 was obtained for a transducer 1 without structures, the measurement curve 22 for a transducer with the holes according to FIGS. 7A, 7B, but without the columnar structures 20.

As can be seen from the measurement curves 22, 21, an increase in the maximum voltage U of approx. 10% is achieved in the present case by the insertion of such structures 20.

FIG. 9 shows a further embodiment of a piezoelectric transducer 1. In addition to the encapsulation 7, the transducer 1 has a further encapsulation 24. While the encapsulation 7 fully encloses the piezoelectric element 2 and the carrier 6 and thus forms the outer surface of the transducer 1, the further encapsulation 24 is arranged within the encapsulation 7. In particular, the further encapsulation 24 is enclosed by the encapsulation 7 from all sides.

The further encapsulation 24 is configure in the present case to encapsulate one or more electronic components 25, in particular to protect them from mechanical or chemical influences. The electronic component 25 is electrically connected to the piezoelectric element 2, in particular to the electrodes 4, 5. For example, the electronic component 25 is connected to the electrodes 4, 5 via conductor tracks of the carrier 6. For example, the electronic component 25 is fixed to the carrier 6 with a conductive adhesive. It is also possible to fix the electronic component 25 directly to the piezoelectric element 2. Here, too, the transducer 1 can also be formed without a carrier 6. Also a fixture via wires is possible.

For example, at least one electronic component 25 is a component for signal processing, such as amplification, filtering or digitization of the signal. In particular, the signal generated in the piezoelectric element 2 can be processed by the electronic component 25 and then provided to the outside, for example to a higher-level regulation or control system, as output signal.

In the present case, the electronic component 25 is not only electrically but also mechanically connected to the piezoelectric element 2. In particular, the electronic component 25 is arranged on the carrier 6 and is thus also exposed to mechanical stresses in the event of deformation of the carrier 6. Mechanical stresses can also be transmitted to the electronic component 25 in other arrangements, for example also through the encapsulation material 7. The electromechanical connection point between the electronic component 25 and the carrier 6 and/or the piezoelectric element 2 is also enclosed by the encapsulation 7.

The further encapsulation 24 is, for example, less flexible than the encapsulation 7. For example, the further encapsulation 24 can have a Shore hardness D > 80 and the encapsulation 7 can have a Shore hardness D 30 to 40. The further encapsulation 7 can also be designed to be even softer, for example with a Shore hardness A greater than or equal to 30. For example, an epoxy resin or polyurethane is used as the material for the further encapsulation 24. The material used for the encapsulation 7 is, for example, the material described for FIG. 1. The degree of hardness of the respective material can be set by the exact chemical composition.

As can be seen in FIG. 9, the electronic component 25 is arranged on the carrier 6 only in certain areas and protrudes beyond the carrier 6. In particular, the electronic component 25 protrudes laterally beyond the carrier 6 with the majority of its volume. Thus, there is less direct coupling of the electronic component 25 to the carrier 6 and the carrier 6 needs not be tailored to the size of the electronic component 25. The further encapsulation 24 may completely enclose the carrier 6 in the width direction, or it may enclose only the electronic component 25, so that in the width direction behind and/or in front of the electronic component 25 the carrier 6 is covered only by the encapsulation 7, but not by the further encapsulation 24.

FIG. 10 shows embodiments of a piezoelectric transducer 1 from the outside. The transducers 1 can each be designed as shown in the previous figures.

The transducers 1 each have a circular base surface. Correspondingly, the respective piezoelectric element 2 and the optionally available carrier 6 also have a circular base surface. The transducers 1 are designed for the application of an external force F from above.

For example, the smaller transducer 1 shown on the left comprises an encapsulation 7 with an outer diameter of 18 mm and a height of 6 mm. For example, the larger transducer 1 shown on the right comprises an encapsulation 7 with an outer diameter of 80 mm and a height of 30 mm.

The piezoelectric element or a composite of carrier and piezoelectric element arranged in the encapsulation 7 has, for example, a diameter of 15 mm for the smaller transducer 1 and a diameter of 70 mm for the larger transducer 1.

FIG. 11 shows another embodiment of a piezoelectric transducer 1 from the outside. The basic structure of the transducer 1 can be as in FIGS. 1 to 9.

In contrast to the preceding figures, the encapsulation 7 has a particular geometric outer shape. In particular, the encapsulation 7 comprises a bridge-like shape. Thereby, the encapsulation 7 comprises a deformation area 28 in which the piezoelectric element 2 is arranged. The piezoelectric element 2 is indicated here by dashed lines. A main surface of the piezoelectric element 2 extends into the image plane in the present case. The main surface of the piezoelectric element 2 is flat. The deformation area 28 is configured to deform when a force is applied. In particular, deformation is provided when a force F is applied from above.

The encapsulation 7 also comprises a support area 29 in the form of two support pillars. The deformation area 28 rests on the support area 29. By means of the support area 29, a downward bending of the deformation area 28 is achieved when force is applied. One or more electronic components 25 may be arranged in the support area 29.

The deformation area 28 has an outwardly curved surface 30. Thus, the encapsulation 7 can also be considered to comprise an arched shape with a cavity. Due to the shape of the curvature, further signal amplification can be achieved. In addition, the curvature defines the point of application of the force F on the encapsulation 7.

FIG. 12 shows a further embodiment of a piezoelectric transducer 1 from the outside. The basic structure of the transducer 1 can be as shown in FIGS. 1 to 9.

The encapsulation 7 here has a deformation area 28 in which the piezoelectric element 2 is arranged. The deformation area 28 is formed in the shape of a thin finger. The piezoelectric element 2 is formed, for example, in the form of a thin strip. The piezoelectric element 2 is configured for application of a force F laterally on the finger shape.

The encapsulation has a support area 29 that acts as a support for the deformation area 28. In particular, the support area 29 is a type of stand for the deformation area 28. One or more electronic components 25 may be arranged in the support area 29.

The encapsulation 7 is uniformly formed and extends over the entire support area 29 and deformation area 28. In particular, the entire encapsulation 7 can be produced in one potting step.

FIG. 13 shows method steps in a method for adjusting the electromechanical properties of a piezoelectric transducer, for example a transducer 1 of one of the embodiments described above. The reference signs used here to designate parts of the transducer refer to possible embodiments, in particular also to the embodiments described above.

In a step A, a piezoelectric element 2 is provided. The piezoelectric element 2 can be arranged on a carrier 6. The piezoelectric element 2 can also be provided without an additional carrier 6. In particular, the piezoelectric element 2 comprises a piezoelectric material 3 and electrodes 4, 5. One or more electronic components 25 may optionally also be provided in this step and electrically connected to the piezoelectric element 2. For example, the electronic components 25 are arranged on a carrier and electrically connected to the piezoelectric element 2 via conductor tracks or wires.

Subsequently, in a step B, the piezoelectric element 2 is enclosed by an encapsulation 7. In particular, in the case of an existing carrier 6, the carrier 6 is also enclosed by the encapsulation. For this purpose, the piezoelectric element 2 with carrier 6 and optionally existing electronic components 25 can be positioned in a mold and subsequently a potting material is introduced into the mold by a potting process, for example by injection molding, overmolding or a defined dispensing of a liquid, so that the composite is enclosed by the potting material. In the case of one or more electronic components, these can also be enclosed by the encapsulation 7.

It is also possible, in an optional step B1, to enclose the electronic components 25 with a further encapsulation 24, as described in connection with FIG. 9. In particular, the further encapsulation 24 can have a higher degree of hardness than the encapsulation 7 in order to protect the electronic components 25 and interfaces to the electrical connection from excessive mechanical stress.

To this end, for example, the electronic components 25 are first electrically connected to the piezoelectric element. After that, a further potting material can be provided and the electronic components 25 can be encapsulated with the further potting material. The further encapsulation 24 thus formed may thereby partially cover the carrier 6 and the piezoelectric element 2. Subsequently, in step B, the encapsulation 7 is applied around the composite of piezoelectric element 2, electronic components 25, optionally present carrier 6 and further encapsulation 24.

In a step C, the electromechanical properties of the transducer 1 thus produced are measured. In particular, an external force F is applied to the transducer 1 for this purpose in order to deform the transducer 1. The electrical signal Sₙ generated due to the deformation by the piezoelectric element 2, in particular the electrical voltage generated, is measured. The signal Sₙ needs not be the direct signal generated by the piezoelectric element 2, but may already have been processed by electronic components 25. For example, an external force F or a deformation path over a time course is specified for this purpose. The electrical signal Sₙ is, for example, an electrical voltage.

Subsequently, it can be determined whether the actual value Sₙ thus obtained corresponds to a desired target value Sₒₚₜ (“Sₙ=Sₒₚₜ ?”). If this is not the case or if this is not yet clear, the process is repeated (n=n+1) so that a further transducer is manufactured in new process steps A, B, whereby the encapsulation 7 of the further transducer 1 differs in its degree of hardness from the encapsulation 7 of the previously manufactured transducer. For example, the degree of hardness can be gradually increased or decreased.

The optimum value can, for example, be a predefined value or a predefined signal threshold, or it can also be determined here whether an increase in the signal has been achieved compared to an already measured signal of a transducer. Depending on whether a further improvement is expected with a further change in the degree of hardness of the encapsulation, the method is repeated or it is decided that one of the encapsulations provides a maximum signal and is used in production. In this case, the electromechanical properties of the transducer are optimally set in step D.

### LIST OF REFERENCE SIGNS

1 transducer
2 piezoelectric element
3 piezoelectric material
4 electrode
5 electrode
6 carrier
7 encapsulation
8 upper side
9 longitudinal side
10 longitudinal side
11 broad side
12 broad side
13 end of the transducer
14 end of the transducer
15 central area
16 active area
17 comparative example of a transducer
18 first encapsulation material (soft)
19 second encapsulation material (hard)
20 structure to improve the coupling
21 transducer without structure
22 transducer with structure
23 top side carrier
24 further encapsulation
25 electronic component
26 electrical interface
27 connection lines
28 deformation area
29 support area
30 surface encapsulation
S signal output by the piezoelectric element
S′ processed signal
Sₙ output signal of the n-th transducer
Sₒₚₜ optimal signal

1. A piezoelectric transducer,
comprising a piezoelectric element and an encapsulation enclosing the piezoelectric element, wherein the encapsulation is configured to set the electromechanical properties of the transducer.

2. The transducer according to claim 1,
wherein the piezoelectric element comprises as piezoelectric material a polymer material.

3. The transducer according to claim 1,
in which the encapsulation has a material with a Shore hardness of A 30 to D 40.

4. The transducer according to claim 1,
in which the encapsulation has a material with a Shore hardness D 30 to 40.

5. The transducer according to claim 1,
in which the encapsulation has a modulus of elasticity which differs by at most 50% from the modulus of elasticity of the piezoelectric element or of a composite of piezoelectric element and carrier of the piezoelectric element.

6. The transducer according to claim 1, comprising a further encapsulation, wherein the further encapsulation has a greater degree of hardness than the encapsulation and wherein the further encapsulation is enclosed by the encapsulation.

7. The transducer according to claim 6, wherein the further encapsulation has a degree of hardness with a Shore hardness D greater than 80 and the encapsulation has a degree of hardness with a Shore hardness between A 30 and D 40.

8. The transducer according to claim 6,
wherein the further encapsulation encloses one or more electronic components.

9. The transducer according to claim 1,
in which the piezoelectric element is arranged on a carrier wherein the encapsulation encloses the piezoelectric element and the carrier.

10. The transducer according to claim 9,
in which the carrier has structures for improving the mechanical coupling with the encapsulation.

11. The transducer according to claim 1,
in which the piezoelectric element is not arranged on a carrier.

12. The transducer according to claim 1,
in which the encapsulation has a curved surface for the application of a force.

13. The transducer according to claim 1,
wherein the encapsulation has a deformation area in which the piezoelectric element is disposed and a support area which supports the deformation area.

14. The transducer according to claim 13,
in which the support area is formed integrally with the deformation area.

15. The transducer according to claim 1,
in which the encapsulation comprises a bridge-shaped geometry.

16. The transducer according to claim 1,
in which the encapsulation comprises a finger-shaped deformation area extending from the support area.

17. The transducer according to claim 13,
in which one or more electrical components are arranged in the support area.

18. A method for setting the electromechanical properties of a transducer, comprising the steps of:
A) Providing a piezoelectric element,
B) Surrounding the piezoelectric element with an encapsulation to form the transducer,
C) Exerting an external force (F) on the transducer and measuring an actual value of a generated electrical signal,
D) Determining whether the measured electrical signal has a desired value and, depending on this, repeating steps A) to C) while changing the degree of hardness of the material of the encapsulation until a desired value is achieved.

19. The method according to claim 18,
in which, when repeating the steps, the measurement in step C) is performed at constant force.

20. The method according to claim 18,
in which before step B), one or more electronic components are provided, are electrically connected to the piezoelectric element and are surrounded by a further encapsulation after the electrical connection.

21. A piezoelectric transducer,
comprising a piezoelectric element and an encapsulation enclosing the piezoelectric element, the encapsulation comprising a deformation area in which the piezoelectric element is arranged and comprising a support area supporting the deformation area.

22. The piezoelectric transducer according to claim 21, wherein the support area is integrally formed with the deformation area.
